(19) United States
(12) Patent Application Publication
(10) Pub. No.: US 2023/0377814 A1
(43) Pub. Date: Nov. 23, 2023

(54) INPUT DEVICE, INPUT SYSTEM, AND DETECTION METHOD

(71) Applicant: Panasonic Intellectual Property Management Co., Ltd., Osaka (JP)

(72) Inventor: Kunio DORO, Okayama (JP)

(21) Appl. No.: 18/044,152

(22) PCT Filed: May 19, 2021
(86) PCT No.: PCT/JP2021/019050

§ 371 Date: Mar. 6, 2023

(30) Foreign Application Priority Data
Sep. 15, 2020 (JP) 2020-154879

(51) Int. Cl. H01H 13/14; H01H 13/20

(52) U.S. Cl. CPC H01H 13/14; H01H 13/20

(57) ABSTRACT

An input device includes a moving member, a pressure sensor, and an inversion member. The moving member moves downward. The pressure sensor is pressed by downward movement of the moving member. The inversion member is configured to, when a magnitude of the downward movement of the moving member exceeds a predetermined threshold value, cause a load applied from the inversion member to the pressure sensor to stop increasing and start decreasing.

### TECHNICAL FIELD

The present disclosure generally relates to an input device, an input system, and a detection method, and more particularly relates to an input device, an input system, and a detection method, each of which uses a pressure sensor.

### BACKGROUND ART

Patent Literature 1 discloses a switch (input system) in which a push button is disposed in a space, formed by assembling a cover onto a base, to be operated slidably in the upward/downward direction. When the push button is pushed down by overcoming the spring force applied by a return spring, a pair of contact terminals turn electrically conductive with each other, thereby outputting an operating signal.

In the switch of Patent Literature 1, the position (operating point) of the push button when the operating signal is output is determined at a fixed position by the mechanical structure of the switch.

### CITATION LIST

### Patent Literature

Patent Literature 1: JP 2015-035402 A

### SUMMARY OF INVENTION

An object of the present disclosure is to provide an input device, an input system, and a detection method, all of which are configured or designed to make the operating point adjustable.

An input device according to an aspect of the present disclosure includes a moving member, a pressure sensor, and an inversion member. The moving member moves downward. The pressure sensor is pressed by downward movement of the moving member. The inversion member is configured to, when a magnitude of the downward movement of the moving member exceeds a predetermined threshold value, cause a load applied from the inversion member to the pressure sensor to stop increasing and start decreasing.

An input system according to another aspect of the present disclosure includes the input device described above; and a processing unit. The inversion member transmits, to the pressure sensor, the load applied to the moving member. The pressure sensor outputs a detection value representing the load applied by the downward movement of the moving member. The processing unit detects, by comparing the detection value with a reference value, that the moving member has moved beyond a certain position corresponding to the reference value.

A detection method according to still another aspect of the present disclosure is designed to use an input device including a moving member, a pressure sensor, an elastic member, and an inversion member. The moving member moves downward. The pressure sensor outputs a detection value representing a load applied by the moving member as the moving member moves downward. The elastic member applies upward force to the moving member. The inversion member transmits, to the pressure sensor, the load applied to the moving member by overcoming the upward force applied by the elastic member. The inversion member is configured to, when a magnitude of the downward movement of the moving member exceeds a predetermined threshold value, cause a load applied from the inversion member to the pressure sensor to stop increasing and start decreasing. The detection method includes an acquisition step and a detection step. The acquisition step includes acquiring the detection value from the pressure sensor. The detection step includes detecting, by comparing the detection value with a reference value, that the moving member has moved beyond a certain position corresponding to the reference value.

### BRIEF DESCRIPTION OF DRAWINGS

FIG. 1 is a perspective view of an input device according to an exemplary embodiment;

FIG. 2 is a plan view of the input device;

FIG. 3 is a cross-sectional view thereof taken along the plane shown in FIG. 2 and illustrating the input device yet to be operated;

FIG. 4 is a cross-sectional view thereof taken along the plane shown in FIG. 2 and illustrating the input device that has been operated;

FIG. 5 is an exploded perspective view of the input device;

FIG. 6 is a block diagram of an electronic device including the input device;

FIG. 7 is a graph showing an exemplary operation of the input device; and

FIG. 8 is a flowchart showing a detection method according to the exemplary embodiment.

### DESCRIPTION OF EMBODIMENTS

An input device 10 and input system 1 according to an exemplary embodiment will be described with reference to the accompanying drawings. Note that the embodiment to be described below is only an exemplary one of various embodiments of the present disclosure and should not be construed as limiting. Rather, the exemplary embodiment may be readily modified in various manners depending on a design choice or any other factor without departing from the scope of the present disclosure. The drawings to be referred to in the following description of embodiments are all schematic representations. Thus, the ratio of the dimensions (including thicknesses) of respective constituent elements illustrated on the drawings does not always reflect their actual dimensional ratio.

### (1) Overview

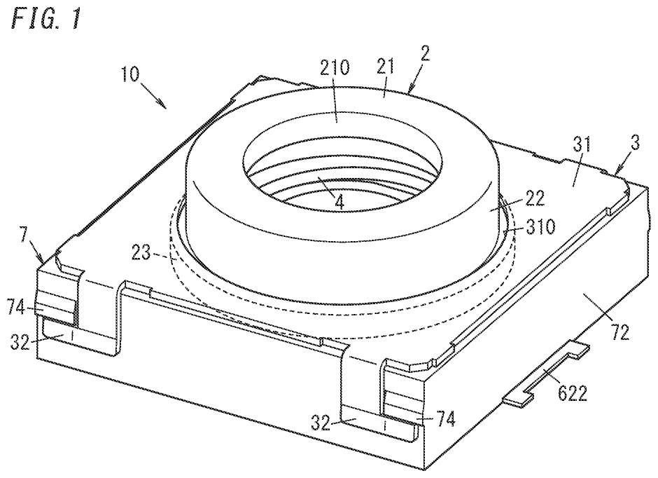

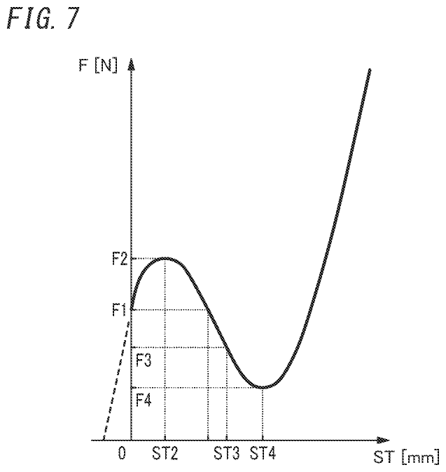

As shown in FIGS. 1-3, an input device 10 according to an exemplary embodiment includes a moving member 2, a pressure sensor 6, and an inversion member 5. The moving member 2 moves downward. The pressure sensor 6 is pressed by downward movement of the moving member 2. The inversion member 5 is configured to, when the magnitude of the downward movement of the moving member 2 exceeds a predetermined threshold value (peak threshold value ST2; refer to FIG. 7), cause a load applied from the inversion member 5 to the pressure sensor 6 to stop increasing and start decreasing.

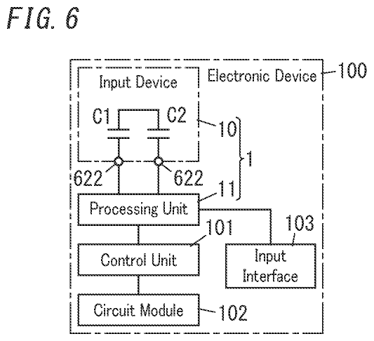

An input system 1 includes the input device 10 and a processing unit 11 (refer to FIG. 6). The inversion member 5 transmits, to the pressure sensor 6, the load applied to the moving member 2. The pressure sensor 6 outputs a detection value representing the load applied by the downward movement of the moving member 2. The processing unit 11 detects, by comparing the detection value with a reference value, that the moving member 2 has moved beyond a certain position (hereinafter referred to as an “operating point”) corresponding to the reference value.

The user may move the moving member 2 downward by operating the moving member 2 (i.e., by applying operating force to the moving member 2). This causes the moving member 2 to move toward the operating point. Also, upon the application of the operating force to the moving member 2, the load is applied from the moving member 2 to the pressure sensor 6 via the inversion member 5. The pressure sensor 6 outputs a detection value representing the load received (i.e., the pressing force).

In this case, the operating point may be adjusted by setting the reference value at an appropriate value. That is to say, providing the input device 10 with the pressure sensor 6 makes the operating point adjustable. As used herein, the operating point refers to the position of the moving member 2 when the processing unit 11 generates an operating signal indicating that the moving member 2 has moved beyond a certain position. In other words, the operating point is the position of the moving member 2 when the processing unit 11 detects an operation performed on the moving member 2. The reference value may be set before the input system 1 is shipped during the manufacturing process of the input system 1, for example. Alternatively, the reference value may also be set by an operation performed by the user on an input interface 103 (refer to FIG. 6), for example.

The input system 1 may be used, for example, for entering a command into any of various types of electronic devices. The input device 10 of the input system 1 may be built in a keyboard for operating a computer, for example. That is to say, the moving member 2 of the input device 10 may be used as a key of the keyboard.

The input system 1 may be held in, for example, a housing of an electronic device 100 (refer to FIG. 6). As the load (pressure) applied to the pressure sensor 6 increases, the detection value of the pressure sensor 6 increases accordingly. When a load, of which the magnitude is equal to or greater than a predetermined value, is applied to the moving member 2 to cause the moving member 2 to move beyond the operating point, the detection value of the pressure sensor 6 reaches the reference value. Then, the processing unit 11 generates an operating signal indicating that the moving member 2 has moved beyond the operating point, and outputs the operating signal to a control unit 101 (refer to FIG. 6) housed in the housing of the electronic device 100. The control unit 101 is configured to perform overall control on the electronic device 100. In accordance with the operating signal supplied from the processing unit 11, the control unit 101 outputs, to a circuit module 102 (refer to FIG. 6) housed in the housing of the electronic device 100, a control signal for controlling the circuit module 102.

Among various types of operations to be performed on the moving member 2, an operation that causes the moving member 2 to go beyond the operating point is a valid operation with respect to the input device 10 and the electronic device 100. On the other hand, an operation that causes the moving member 2 not to go beyond the operating point is an invalid operation with respect to the input device 10 and the electronic device 100.

When the moving member 2 is operated to go beyond the operating point, the electronic device 100 makes a predetermine response. The magnitude of movement of the moving member 2 when the electronic device 100 makes the predetermined response varies according to the reference value. Thus, the response speed of the electronic device 100 that the user feels may be increased or decreased by adjusting the reference value. The input device 10 according to the present disclosure is particularly effectively usable as an input device (such as a keyboard) for e-sports, in which the response speed should be increased albeit slightly.

Meanwhile, as a comparative example for the input system 1 according to this embodiment, suppose a situation where the processing unit 11 detects, based on the opened and closed states of contacts to be opened and closed as the moving member 2 moves, that the moving member 2 has moved beyond the operating point. In the comparative example, if the contact resistance of the contacts has increased, for example, the processing unit 11 may fail to accurately detect that the moving member 2 has moved beyond the operating point. In contrast, the input system 1 according to this embodiment may reduce the chances of making such inaccurate detection.

Note that the terms “down” and “downward” as used herein just refer to the direction in which the moving member 2 moves when operated and should not be construed as limiting the direction in which the input device 10 is used. Rather the input device 10 may also be used in such an orientation that makes “down” (downward) as used herein upward, forward, backward, leftward, or rightward, for example.

Likewise, the terms “up” and “upward” as used herein just refer to the direction opposite from the direction referred to by the terms “down” and “downward” and should not be construed as limiting the direction in which the input device 10 is used. Rather the input device 10 may also be used in such an orientation that makes “up” (upward) as used herein downward, forward, backward, leftward, or rightward, for example.

### (2) Details

Next, an input system 1 according to this embodiment will be described in further detail. The respective constituent elements of the input system 1 will be described on the supposition that no load is applied by operation to the moving member 2 unless otherwise stated.

As shown in FIG. 6, the input system 1 includes the input device 10 and the processing unit 11. The input system 1 preferably further includes the control unit 101 and the input interface 103.

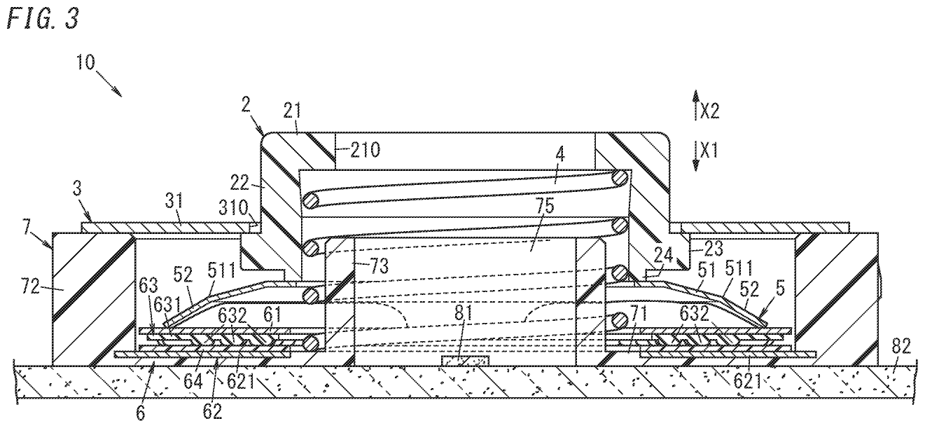

As shown in FIGS. 1-5, the input device 10 includes the moving member 2, a cover 3, an elastic member 4, the inversion member 5, the pressure sensor 6, and a housing 7. In addition, as shown in FIG. 3, the input device 10 further includes a light source 81 and a board 82 on which the light source 81 is mounted.

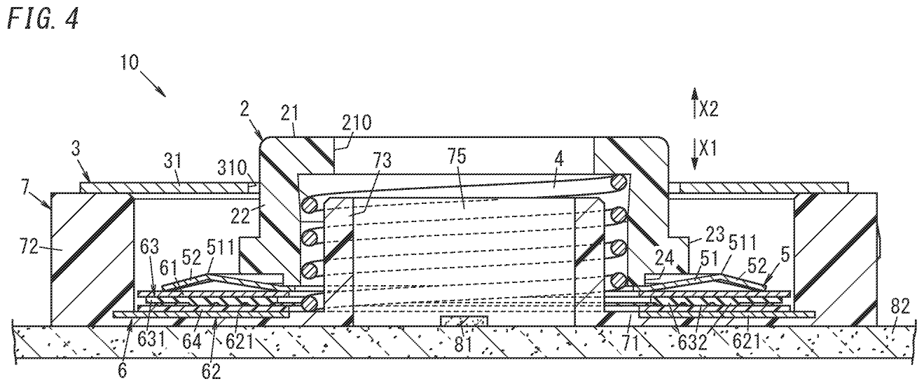

The moving member 2 and the pressure sensor 6 are arranged one on top of the other in the upward/downward direction. The pressure sensor 6 is disposed under the moving member 2 when viewed from the moving member 2. The moving member 2 is disposed over the pressure sensor 6 when viewed from the pressure sensor 6. In FIG. 4, a first direction X1 corresponds to the downward direction and a second direction X2 corresponds to the upward direction. Note that the arrows indicating the first direction X1 and the second direction X2 are shown in FIG. 4 just for illustrative purposes and are insubstantial ones.

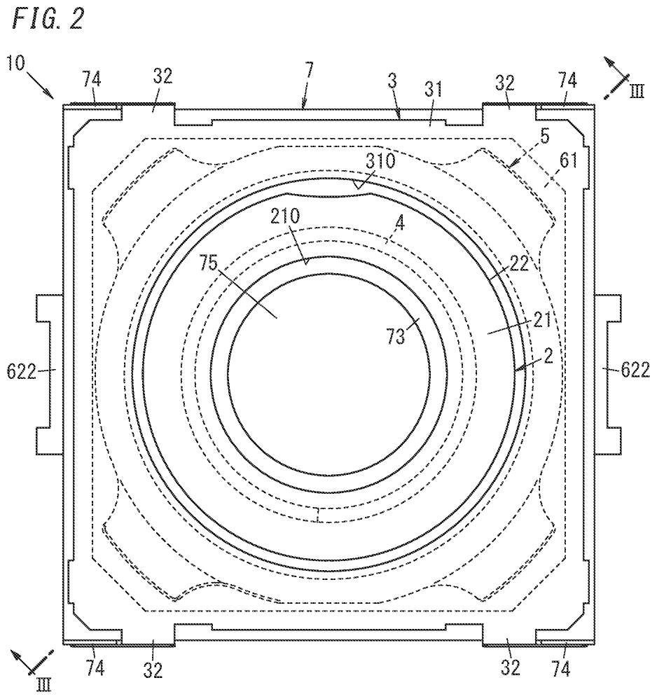

In the following description of embodiments, the direction in which two terminals 622 (refer to FIG. 2) to be described later are arranged side by side is herein defined to be the rightward/leftward direction and the direction perpendicular to both the upward/downward direction the rightward/leftward direction is herein defined to be a forward/backward direction. Nevertheless, these directions are not defined to limit the direction in which the input device 10 is used to any particular direction.

### (2.1) Housing

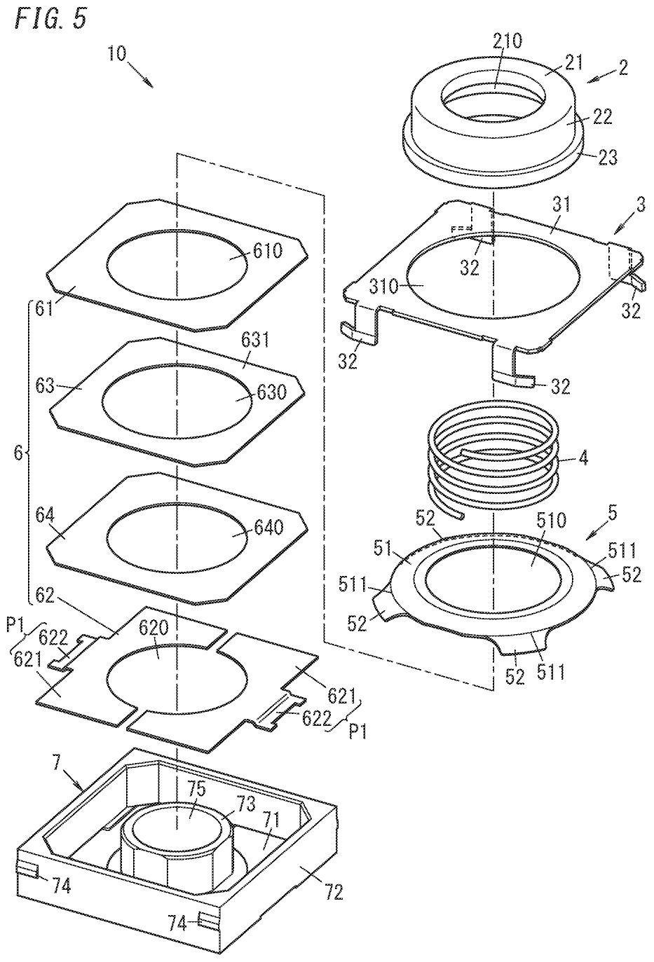

As shown in FIG. 5, the housing 7 includes a bottom wall 71, peripheral walls 72, an inner cylindrical portion 73, and a plurality of (e.g., four in this embodiment; refer to FIG. 2) hooks 74.

The bottom wall 71 has a rectangular plate shape. As used herein, the “rectangular” is a concept including squares and rectangles. The peripheral walls 72 protrude from the outer edges of the bottom wall 71 along the thickness of the bottom wall 71 (i.e., protrude upward). Thus, the housing 7 is formed in the shape of a box with an open top. In top view, parts, respectively corresponding to the four corners, of the inner edges of the peripheral walls 72 are chamfered.

The inner cylindrical portion 73 has a circular cylindrical shape. The inner cylindrical portion 73 protrudes, from a circular area surrounding the center of the bottom wall 71, along the thickness of the bottom wall 71 (i.e., protrudes upward). In addition, a part, located inside the inner cylindrical portion 73, of the bottom wall 71 is open. That is to say, the housing 7 has a penetrating part 75. The penetrating part 75 is a cavity that covers the internal space of the inner cylindrical portion 73 and the opening of the bottom wall 71. The penetrating part 75 penetrates through the housing 7 in the upward/downward direction. In top view, the penetrating part 75 has a circular shape.

The plurality of (e.g., four) hooks 74 are projections protruding from the outer surfaces of the peripheral walls 72. As shown in FIG. 2, two hooks 74 out of the four hooks 74 protrude from the front surface of the peripheral walls 72 and are arranged side by side in the rightward/leftward direction. The other two hooks 74 protrude from the rear surface of the peripheral walls 72 and are arranged side by side in the rightward/leftward direction.

### (2.2) Cover

The cover 3 is made of a metallic material. The cover 3 includes a cover body 31 and a plurality of (e.g., four in this embodiment) hooking claws 32.

The cover body 31 has a rectangular plate shape. The thickness of the cover body 31 is aligned with the upward/downward direction. The cover body 31 is in contact with the top surface of the peripheral walls 72 of the housing 7. The cover body 31 cover the housing 7 from over the housing 7. The cover body 31 has a penetrating part 310, which is a through hole penetrating through the cover body 31. The penetrating part 310 is provided through an area including the center of the cover body 31. In top view, the penetrating part 310 has a circular shape. The moving member 2 is disposed inside the penetrating part 310.

The plurality of (e.g., four) hooking claws 32 protrude from the cover body 31. Each of these hooking claws 32 protrudes downward from the cover body 31 and then further protrudes from its bottom either leftward or rightward.

Two hooking claws 32 out of the four hooking claws 32 protrude from the front edge of the cover body 31 and are arranged side by side in the rightward/leftward direction. The other two hooking claws 32 protrude from the rear edge of the cover body 31 and are arranged side by side in the rightward/leftward direction.

The plurality of hooking claws 32 correspond one to one to the plurality of hooks 74 of the housing 7. Each of the hooking claws 32 is hooked on a corresponding one of the hooks 74. This allows the housing 7 and the cover 3 to be joined together. That is to say, the housing 7 and the cover 3 are joined together by snap-fitting. The plurality of hooking claws 32 and the plurality of hooks 74 serve as a joining structure for joining the housing 7 and the cover 3 together.

### (2.3) Pressure Sensor

The pressure sensor 6 is a capacitive pressure sensor. As shown in FIGS. 3 and 5, the pressure sensor 6 includes a first electrode 61, a second electrode 62, an intermediate member 63, and an insulating sheet 64.

The intermediate member 63 has elasticity. The intermediate member 63 is interposed between the first electrode 61 and the second electrode 62. The insulating sheet 64 is interposed between the intermediate member 63 and the second electrode 62. More specifically, the first electrode 61, the intermediate member 63, the insulating sheet 64, and the second electrode 62 are arranged in this order one on top of another in the upward/downward direction such that the first electrode 61 is located at the top and the second electrode 62 is located at the bottom.

### (2.3.1) First Electrode and Second Electrode

Each of the first electrode 61 and the second electrode 62 is a metallic plate having electrical conductivity. The first electrode 61 and the second electrode 62 are electrically insulated from each other.

The first electrode 61 has a rectangular plate shape. The first electrode 61 has a penetrating part 610, which is a through hole penetrating through the first electrode 61. The penetrating part 610 is provided through an area including the center of the first electrode 61. In top view, the penetrating part 610 has a circular shape. Inside the penetrating part 610, disposed is the inner cylindrical portion 73 of the housing 7.

The second electrode 62 has a rectangular plate shape. The second electrode 62 has a penetrating part 620, which is a through hole penetrating through the second electrode 62. The penetrating part 620 is provided through an area including the center of the second electrode 62. In top view, the penetrating part 620 has a circular shape. Inside the penetrating part 620, disposed is the inner cylindrical portion 73 of the housing 7.

The second electrode 62 is integrated with the housing 7 by insert molding. That is to say, the housing 7 is insert molded by using the second electrode 62 as an insert member.

In addition, the second electrode 62 is divided into two electrode pieces P1. That is to say, the second electrode 62 includes two electrode pieces P1. The two electrode pieces P1 are arranged side by side in the rightward/leftward direction. These two electrode pieces P1 are electrically insulated from each other. The penetrating part 620 is provided between the two electrode pieces P1.

Each of the two electrode pieces P1 includes an electrode body 621 and a terminal 622. That is to say, the second electrode 62 includes two electrode bodies 621 and two terminals 622.

In top view, each of the two electrode bodies 621 has a U-shape. The two electrode bodies 621 are arranged side by side in the rightward/leftward direction to be spaced from each other with their tips facing each other. The two electrode bodies 621 are electrically insulated from each other. The two electrode bodies 621 face the first electrode 61 via the insulating sheet 64 and the intermediate member 63.

Each of the two terminals 622 is exposed out of the housing 7. More specifically, one of the two terminals 622 is exposed to the right of the housing 7 and the other terminal 622 is exposed to the left of the housing 7. These two terminals 622 are mechanically joined and electrically connected by soldering, for example, to an electrically conductive member on the board 82 (refer to FIG. 3), for example. As a soldering technique, reflow soldering or DIP soldering may be adopted, for example. The two terminals 622 are electrically connected to the processing unit 11 (refer to FIG. 6).

In each of the two electrode pieces P1, the terminal 622 is connected to the electrode body 621. The terminal 622 extends through the housing 7 from the inside of the housing 7 to the outside of the housing 7.

### (2.3.2) Insulating Sheet

The second electrode 62 and the intermediate member 63 are electrically insulated from each other via an insulating layer. In this embodiment, the insulating sheet 64 serves as the insulating layer.

The insulating sheet 64 has electrical insulation properties. The insulating sheet 64 has a rectangular plate shape. The insulating sheet 64 has a penetrating part 640, which is a through hole penetrating through the insulating sheet 64. The penetrating part 640 is provided through an area including the center of the insulating sheet 64. In top view, the penetrating part 640 has a circular shape. Inside the penetrating part 640, disposed is the inner cylindrical portion 73 of the housing 7.

### (2.3.3) Intermediate Member

The intermediate member 63 is made of rubber with electrical conductivity. More specifically, the intermediate member 63 is formed by uniformly dispersing electrically conductive particles such as carbon particles in rubber that is an insulator. Examples of methods for molding the intermediate member 63 include liquid injection molding (LIM).

The intermediate member 63 is formed in a plate shape as a whole. The intermediate member 63 has a rectangular outer peripheral edge shape when viewed along the thickness of the intermediate member 63. The intermediate member 63 faces the two electrode bodies 621 of the second electrode 62 via the insulating sheet 64. The intermediate member 63 and the second electrode 62 are electrically insulated from each other by the insulating sheet 64.

The intermediate member 63 has a penetrating part 630, which is a through hole penetrating through the intermediate member 63. The penetrating part 630 is provided through an area including the center of the intermediate member 63. In top view, the penetrating part 630 has a circular shape. Inside the penetrating part 630, disposed is the inner cylindrical portion 73 of the housing 7.

As shown in FIG. 3, the intermediate member 63 includes a base portion 631 and a plurality of projections 632. The base portion 631 has a plate shape. The base portion 631 has a rectangular outer peripheral edge shape. Out of the two surfaces along the thickness of the base portion 631, the surface facing the first electrode 61 (i.e., the upper surface) is in contact with the first electrode 61, thus making the intermediate member 63 electrically connected to the first electrode 61. The plurality of projections 632 protrudes from the surface (i.e., the lower surface) facing the second electrode 62 out of the two surfaces along the thickness of the base portion 631.

The intermediate member 63 is in contact with the insulating sheet 64 at the plurality of projections 632. Bringing the intermediate member 63 into contact with the insulating sheet 64 at the plurality of projections 632, not on the base portion 631, stabilizes the condition of contact between the intermediate member 63 and the insulating sheet 64.

Upon the application of the operating force to the moving member 2, the load is transmitted from the moving member 2 to the pressure sensor 6 via the inversion member 5. The intermediate member 63 is compressed under this load. More specifically, the intermediate member 63 is compressed in the upward/downward direction, thus shortening the distance between the first electrode 61 and the second electrode 62. Upon removal of the operating force, the intermediate member 63 recovers its original shape that the intermediate member 63 assumed before the operating force was applied thereto.

As the moving member 2 is pushed downward, the intermediate member 63 is compressed in the upward/downward direction and deformed to expand in a direction perpendicular to the upward/downward direction. As the intermediate member 63 is deformed, the electrostatic capacitance between the intermediate member 63 and the (two electrode pieces P1 of the) second electrode 62 varies. The pressure sensor 6 outputs an analog electrical signal (detection value), including information about the variation in the electrostatic capacitance, from the two terminals 622. The processing unit 11 (refer to FIG. 6) performs processing based on the detection value provided by the pressure sensor 6. Note that in FIG. 6, a capacitor that uses one electrode piece P1 out of the two electrode pieces P1 and the intermediate member 63 as counter electrodes is designated by Cl and a capacitor that uses the other electrode piece P1 and the intermediate member 63 as counter electrodes is designated by C2.

The pressure sensor 6 outputs, as the detection value, an electrical signal representing a combined capacitance of the capacitors C1, C2. This allows the processing unit 11 to measure, based on the combined capacitance, the magnitude of the load applied to the pressure sensor 6.

Any of various known methods may be adopted as a method for allowing the processing unit 11 to measure the electrostatic capacitance (i.e., the combined capacitance described above). For example, a switched capacitor method may be adopted. According to the switched capacitor method, (a variation in) the electrostatic capacitance of a target capacitor is measured based on the quantity of the electric charge stored in the target capacitor (where the intermediate member 63 and the second electrode 62 are used as a pair of counter electrodes) as the target of measurement. The switched capacitor method requires, for example, alternately performing charge processing of charging the target capacitor for a predetermined time and discharge processing of discharging electricity from the target capacitor and charging a capacitor for decision with the charge that has been stored in the target capacitor. Charging and discharging are performed via the two terminals 622. When the voltage across the capacitor for decision reaches a prescribed value, the discharge processing is finished, and the charge processing is started instead. That is to say, the larger the electrostatic capacitance of the target capacitor is, the larger the number of times the voltage across the capacitor for decision reaches a prescribed value during a predetermined time is. Thus, the electrostatic capacitance of the target capacitor may be measured based on the number of times the voltage across the capacitor for decision reaches the prescribed value during the predetermined time.

### (2.4) Inversion Member

The inversion member 5 transmits, to the pressure sensor 6, the load applied to the moving member 2 by overcoming the force applied in the second direction X2 (i.e., in the upward direction) from the elastic member 4. When the magnitude of movement of the moving member 2 in the first direction X1 (i.e., in the downward direction), which has been less than a peak threshold value ST2, exceeds the peak threshold value ST2, the load applied from the inversion member 5 to the pressure sensor 6 stops increasing and starts decreasing. That is to say, the direction of change of the load inverts.

The inversion member 5 is a leaf spring. The inversion member 5 is a so-called “metal dome.” The inversion member 5 may be configured as, for example, a metallic plate of stainless steel (SUS), for example. As shown in FIG. 5, the inversion member 5 includes a body 51 and a plurality of (e.g., four in the example shown in FIG. 5) legs 52.

In top view, the body 51 has a ringlike shape. That is to say, the body 51 has a penetrating part 510, which is a through hole penetrating through the body 51. The penetrating part 510 is provided through an area including the center of the body 51. In top view, the penetrating part 510 has a circular shape. Inside the penetrating part 510, disposed is the inner cylindrical portion 73 of the housing 7.

The plurality of legs 52 protrudes from the outer peripheral edge of the body 51. The plurality of legs 52 protrudes along the radius of the body 51 obliquely downward from the body 51. The plurality of legs 52 are arranged at regular intervals along the circumference of the body 51. The plurality of (e.g., four) legs 52 correspond one to one to the four corners of the inner edges of the peripheral walls 72 of the housing 7. Each leg 52 is disposed adjacent to its corresponding corner.

As shown in FIG. 3, the inversion member 5 is formed such that a central portion thereof is convex up. That is to say, the inversion member 5 has a dome shape.

The upper surface of the body 51 is in contact with the moving member 2. More specifically, a peripheral edge portion surrounding the penetrating part 510 of the body 51 is in contact with the moving member 2. The respective tips of the plurality of legs 52 are in contact with the first electrode 61 of the pressure sensor 6. In this manner, the inversion member 5 is interposed between the moving member 2 and the pressure sensor 6.

Upon the application of a load, of which the magnitude is equal to or greater than a predetermined value, to the moving member 2 as a result of the operation performed by the user, the inversion member 5 is buckled and deformed under the load received from the moving member 2. Specifically, the inversion member 5 is folded at a folding part 511 to be deformed such that the central part thereof becomes convex down as shown in FIG. 4. As used herein, the “folding part” refers to the boundary between a convex portion and a concave portion of the inversion member 5 which are formed when the inversion member 5 is folded upon the application of force of a predetermined magnitude or more to the moving member 2. As used herein, the “concave portion” refers to a region closer to the center of the inversion member 5 shown in FIG. 4 and the “convex portion” refers to a region located outside of the concave portion. When no force is applied to the inversion member 5, the folding part 511 does not have to be distinguishable in appearance from the other parts of the inversion member 5.

The folding part 511 according to this embodiment refers to the boundary between the body 51 and each of the plurality of legs 52 (refer to FIG. 5).

When the inversion member 5 is buckled and deformed, the load applied from the inversion member 5 to the pressure sensor 6 decreases steeply. In addition, when the inversion member 5 is buckled and deformed, the load applied from the moving member 2 to the user (operator) also decreases steeply. This gives the user a sense of clicking.

When no load is applied any longer from the user to the moving member 2, the inversion member 5 recovers its original shape that the inversion member 5 assumed before the load was applied from the user to the moving member 2.

### (2.5) Moving Member

The moving member 2 is the target to be operated by the user. The user may operate the moving member 2 either directly by putting one of his or her fingers on the moving member 2 or indirectly via a member other than the moving member 2.

The moving member 2 may be made of a synthetic resin, for example. The moving member 2 preferably has a light-transmitting property.

As shown in FIG. 3, the moving member 2 includes a top portion 21, a sidewall 22, a brim 23, and a rib 24.

The top portion 21 has a disc shape. The thickness of the top portion 21 is aligned with the upward/downward direction. The top portion 21 has a through hole 210, which penetrates through the top portion 21. The through hole 210 is provided through an area including the center of the top portion 21. In top view, the through hole 210 has a circular shape.

The sidewall 22 has a circular cylindrical shape. The sidewall 22 protrudes downward from the outer peripheral edge of the top portion 21.

In top view, the brim 23 has an annular shape. The brim 23 protrudes from the outer surface of the sidewall 22 along the radius of the sidewall 22.

In bottom view, the rib 24 has an annular shape. The rib 24 protrudes downward from the bottom of the sidewall 22. The inside diameter of the rib 24 is equal to the inside diameter of the sidewall 22. The outside diameter of the rib 24 is smaller than the outside diameter of the sidewall 22.

The sidewall 22 is passed through the penetrating part 310 of the cover body 31. As shown in FIG. 3, while no load is applied by operation to the moving member 2, the upper surface of the brim 23 is in contact with the lower surface of the cover body 31. Meanwhile, the lower surface of the rib 24 is in contact with the upper surface of the body 51 of the inversion member 5.

While no load is applied by operation to the moving member 2, the inversion member 5 is pushed by the moving member 2 with relatively small force and flexed. Thus, upward elastic force is applied from the inversion member 5 to the moving member 2. However, the upper surface of the brim 23 is in contact with the lower surface of the cover body 31, thus restricting the upward movement of the moving member 2. That is to say, the cover body 31 (cover 3) applies reactive force to the moving member 2 against the elastic force applied from the inversion member 5.

As can be seen, the cover body 31 serves as a preloading member for maintaining the preloading state of the input system 1. As used herein, the “preloading state” refers to a state where load is applied from the moving member 2 to the pressure sensor 6 while the moving member 2 is not operated. That is to say, in the preloading state, the reactive force (load) applied from the cover body 31 to the moving member 2 is transmitted to the pressure sensor 6 via the inversion member 5.

### (2.6) Elastic Member

The elastic member 4 applies upward biasing force to the moving member 2. The elastic member 4 is compressed by the downward movement of the moving member 2. The elastic member 4 according to this embodiment is a compression coil spring. The expansion/compression direction of the elastic member 4 is aligned with the upward/downward direction. A spring seat at the upper end of the elastic member 4 is in contact with the top portion 21 of the moving member 2. On the other hand, a spring seat at the lower end of the elastic member 4 is in contact with the bottom wall 71 of the housing 7. That is to say, the elastic member 4 is sandwiched between the moving member 2 and the housing 7. The elastic member 4 is disposed around the inner cylindrical portion 73 of the housing 7.

While no load is applied by operation to the moving member 2, upward biasing force is applied from the elastic member 4 to the moving member 2 and upward force is also applied from the inversion member 5 to the moving member 2. This keeps the upper surface of the brim 23 of the moving member 2 in contact with the lower surface of the cover body 31.

### (2.7) Board and Light Source

The board 82 may be, for example, a printed wiring board. The housing 7 is fixed on the board 82. In addition, the two terminals 622 of the second electrode 62 are electrically connected to the board 82. Furthermore, the light source 81 is mounted on the board 82.

The light source 81 may be, for example, a light-emitting diode element. The light source 81 emits light with power supplied. The light source 81 is disposed inside the inner cylindrical portion 73 of the housing 7. The light emitted from the light source 81 passes through the through hole 210 of the moving member 2 and radiated into the space over the moving member 2. This allows the surface of the moving member 2 to be decorated with the light, thus making the input device 10 an impressive one.

### (2.8) Processing Unit

The processing unit 11 (refer to FIG. 6) includes a computer system including one or more processors and one or more memories. At least some of the functions of the processing unit 11 are performed by making the one or more processors execute a program stored in the memory. The program may be stored in advance in the memory. The program may also be downloaded via a telecommunications line such as the Internet or distributed after having been stored in a non-transitory storage medium such as a memory card.

The processing unit 11 detects, by comparing the detection value provided by the pressure sensor 6 with a reference value, that the moving member 2 has moved beyond a certain position (i.e., the operating point) corresponding to the reference value. More specifically, when finding the detection value equal to the reference value, the processing unit 11 detects that the moving member 2 has moved beyond the operating point. On the other hand, when finding the detection value not equal to the reference value, the processing unit 11 does not detect that the moving member 2 has moved beyond the operating point. The reference value is stored in advance in the memory.

Note that as used herein, if some value is “equal to” another, these two values do not have to be exactly equal to each other but may also be different from each other within a tolerance range. For example, the expression “the detection value is “equal to” the reference value” means that the difference between the detection value and the reference value is a value falling within a predetermined range including 0.

On detecting that the moving member 2 has moved beyond the operating point, the processing unit 11 outputs the operating signal.

### (2.9) Control Unit

The control unit 101 controls the circuit module 102 in accordance with the operating signal supplied from the processing unit 11.

The control unit 101 includes a computer system including one or more processors and one or more memories. At least some of the functions of the control unit 101 are performed by making the one or more processors execute a program stored in the memory. The program may be stored in advance in the memory. The program may also be downloaded via a telecommunications line such as the Internet or distributed after having been stored in a non-transitory storage medium such as a memory card.

### (2.10) Circuit Module

The circuit module 102 performs processing to allow the electronic device 100 to perform a predetermined function. For example, if the electronic device 100 is a keyboard for use to operate a computer terminal, then the operation of pushing the moving member 2 corresponds to key input. In accordance with the operating signal supplied from the processing unit 11 in response to the key input, the control unit 101 outputs a control signal to the circuit module 102. In response to the control signal, the circuit module 102 transmits a signal indicating whether or not there is any key input to the computer terminal.

### (2.11) Input Interface

The input interface 103 accepts the operation of setting the reference value. The input interface 103 includes at least one of a switch, a dip switch, or a dial, for example.

The input interface 103 may be a constituent element of the input system 1.

### (3) Exemplary Operation

Next, an exemplary operation of the input system 1 will be described with reference to FIG. 7.

In FIG. 7, the abscissa indicates the magnitude of movement (hereinafter referred to as a “stroke ST”) of the moving member 2 in the first direction X1. In this case, the magnitude of movement of the moving member 2 in a state where the moving member 2 is not operated is supposed to be 0. In FIG. 7, the ordinate indicates the magnitude of the load (hereinafter referred to as a “sensor load F”) applied to, and detected by, the pressure sensor 6. The relationship between the stroke ST and the sensor load F is determined depending on a characteristic concerning the deformation of the elastic member 4 (compression coil spring) and a characteristic concerning the deformation of the inversion member 5.

Even while the moving member 2 is not operated, the load (preload) is also applied from the cover body 31 (preloading member) to the pressure sensor 6 via the moving member 2 and the inversion member 5. Thus, the sensor load F is greater than 0. A relationship between the stroke ST and the sensor load F in a situation where the cover body 31 is not provided and no preload is applied to the pressure sensor 6 is indicated by the dotted curve in FIG. 7 for your reference.

In the input system 1 according to this embodiment, in a state where the moving member 2 is not operated, the stroke ST=0 and the sensor load F=F1, where F1 is the load applied as preload to the pressure sensor 6.

In a range where the stroke ST is equal to or greater than 0 and equal to or less than the peak threshold value ST2, as the stroke ST increases, the sensor load F also increases monotonically. When the stroke ST is equal to the peak threshold value ST2, the sensor load F reaches a local maximum value F2.

In a range where the stroke ST is equal to or greater than the peak threshold value ST2 and equal to or less than a bottom threshold value ST4, as the stroke ST increases, the sensor load F decreases monotonically. When the stroke ST is equal to the bottom threshold value ST4, the sensor load F reaches a local minimum value F4.

While the stroke ST increases from a value less than the peak threshold value ST2 to a value greater than the peak threshold value ST2, the inversion member 5 is buckled and deformed. This causes the sensor load F to decrease steeply. In addition, the load applied from the moving member 2 to the user also decreases steeply at this time. This gives the user a sense of clicking.

In a range where the stroke ST is greater than the bottom threshold value ST4, as the stroke ST increases, the sensor load F increases monotonically.

The reference value F3 is set such that in a situation where the magnitude of movement of the moving member 2 increases monotonically from 0, after the load applied by the inversion member 5 to the user via the moving member 2 has stopped increasing and started decreasing, the detection value of the pressure sensor 6 (i.e., the sensor load F) reaches the reference value F3. That is to say, the reference value F3 is set at a value equal to or less than the local maximum value F2 of the sensor load F and equal to or greater than the local minimum value F4 thereof.

More specifically, the reference value F3 is a value corresponding to a load lighter than the load F1 applied to the pressure sensor 6 in the preloading state. In other words, the processing unit 11 uses, as the reference value F3, a value corresponding to the load lighter than the load F1 applied to the pressure sensor 6 in the preloading state.

Meanwhile, in a situation where the magnitude of the load applied to the moving member 2 is increased gradually, the local minimum value F4 is the minimum value of the sensor load F.

That is to say, while the load applied to the moving member 2 increases from the preloading state, the load transmitted from the inversion member 5 to the pressure sensor 6 when the magnitude of movement (stroke ST) is the bottom threshold value ST4 becomes the minimum value (local minimum value F4). The processing unit 11 uses, as the reference value F3, a value equal to or greater than the minimum value (local minimum value F4).

In sum, the reference value F3 is set at a value equal to or less than the load F1 applied to the pressure sensor 6 in the preloading state and equal to or greater than the local minimum value F4. The reference value F3 thus set is a value corresponding to only one magnitude of movement (stroke ST) in the range where the magnitude of movement (stroke ST) of the moving member 2 is equal to or greater than 0 and equal to or less than the bottom threshold value ST4. This enables reducing the chances of the processing unit 11 detecting by mistake, before the stroke ST reaches a value ST3 corresponding to the reference value F3, that the moving member 2 has moved beyond the operating point.

The processing unit 11 detects, when finding the detection value of the pressure sensor 6 (sensor load F) equal to the reference value F3, that the moving member 2 has moved beyond the operating point. That is to say, the processing unit 11 detects, when finding that the stroke ST has reached the value ST3 corresponding to the reference value F3, that the moving member 2 has moved beyond the operating point.

When the user stops applying the load to the moving member 2, the inversion member 5 recovers its original shape that the inversion member 5 assumed before the moving member 2 was operated. In addition, the elastic member 4 also recovers its original shape that the elastic member 4 assumed before the moving member 2 was operated. As a result, the moving member 2 returns to its home position as shown in FIG. 3 where the moving member 2 was located before being operated.

As described above, when the moving member 2 is operated to make the moving member 2 go beyond the operating point, the electronic device 100 (refer to FIG. 6) makes a predetermined response. The magnitude of movement (stroke ST) of the moving member 2 when the electronic device 100 makes a predetermined response varies according to the reference value. If the reference value is set to make the moving member 2 go beyond the operating point when the load applied to the moving member 2 is relatively heavy while the stroke ST falls within the range from the peak threshold value ST2 to the bottom threshold value ST4, then the user feels that it takes a relatively short time for the electronic device 100 to make the predetermined response. In other words, the user feels that the response speed is relatively fast. On the other hand, if the reference value is set to make the moving member 2 go beyond the operating point when the load applied to the moving member 2 is relatively light while the stroke ST falls within the range from the peak threshold value ST2 to the bottom threshold value ST4, then the user feels that the response speed is relatively slow. That is to say, the response speed that the user feels may be increased or decreased by adjusting the reference value.

### Variations

Next, variations of the exemplary embodiment will be enumerated one after another. Optionally, the variations to be described below may be adopted in combination as appropriate.

The processing unit 11 may be configured to, when finding the detection value equal to or less than the reference value, detect that the moving member 2 has moved beyond the operating point but when finding the detection value greater than the reference value, not to detect that the moving member 2 has moved beyond the operating point.

The input system 1 itself may be used as at least a part of the input interface 103. The input interface 103 may be, for example, a keyboard including a plurality of input systems 1.

Alternatively, a plurality of input systems 1 may be provided and some input system 1 may be used as at least a part of the input interface 103 of another input system 1.

If a plurality of input systems 1 are provided, the plurality of input systems 1 may share either a single processing unit 11 or a plurality of processing units 11.

The input system 1 does not have to be used in a keyboard. The input system 1 may be used in various types of electronic devices. For example, the input system 1 may be used in a lighting fixture. That is to say, the moving member 2 may also be used as a button subjected to an operation of changing the lighting state of the light source of the lighting fixture.

A plurality of reference values may be set. For example, a first reference value and a second reference value may be set as the plurality of reference values. The electronic device 100 that uses the input system 1 may make a different response depending on whether the detection value of the pressure sensor 6 is equal to the first reference value or the second reference value.

The intermediate member 63 does not have to have electrical conductivity. Even so, compressing the intermediate member 63 in the upward/downward direction also makes the distance between the first electrode 61 and the second electrode 62 shorter, thus changing the electrostatic capacitance between the first electrode 61 and the second electrode 62. The pressure sensor 6 may detect, based on the electrostatic capacitance, the pressure applied to the pressure sensor 6 itself.

The elastic member 4 does not have to be a compression coil spring. Alternatively, the elastic member 4 may also be, for example, a leaf spring or a piece of rubber.

The two electrode pieces P1 of the second electrode 62 may each include a second insulation displacement contact to be connected mechanically and electrically to a first insulation displacement contact held on the board 82.

The pressure sensor 6 does not have to be a capacitive pressure sensor. Alternatively, the pressure sensor 6 may also be, for example, a resistive strain sensor for transforming a variation in electrical resistance into an electrical signal or a magnetostrictive stain sensor for transforming a variation in magnetic permeability into an electrical signal.

The insulating layer between the intermediate member 63 and the second electrode 62 does not have to be configured as the insulating sheet 64. Alternatively, the insulating layer may also be the air, for example. That is to say, the input device 10 may have a structure for regulating the positional relationship between the intermediate member 63 and the second electrode 62 to create an air gap between the intermediate member 63 and the second electrode 62.

In the exemplary embodiment described above, the inversion member 5 is configured as a single leaf spring. Alternatively, the inversion member 5 may also be formed by stacking a plurality of leaf springs one on top of another. In that case, the magnitude of force required to buckle and deform the inversion member 5 varies, and the operator of the input device 10 feels a different sense, according to the number of the leaf springs stacked one on top of another.

Optionally, the functions of the input system 1 may also be implemented as, for example, a detection method, a (computer) program, or a non-transitory storage medium on which the program is stored.

A detection method according to an aspect is designed to use an input device 10 including a moving member 2, a pressure sensor 6, an elastic member 4, and an inversion member 5. The moving member 2 moves downward. The pressure sensor 6 outputs a detection value representing a load applied by the moving member 2 as the moving member 2 moves downward. The elastic member 4 applies upward force to the moving member 2. The inversion member 5 transmits, to the pressure sensor 6, the load applied to the moving member 2 by overcoming the upward force applied by the elastic member 4. The inversion member 5 is configured to, when a magnitude of the downward movement of the moving member 2 exceeds a predetermined threshold value (peak threshold value ST2), cause the load applied from the inversion member 5 to the pressure sensor 6 to stop increasing and start decreasing. The detection method includes an acquisition step and a detection step. The acquisition step includes acquiring the detection value (sensor load F) from the pressure sensor 6. The detection step includes detecting, by comparing the detection value with a reference value F3, that the moving member 2 has moved beyond a certain position corresponding to the reference value F3.

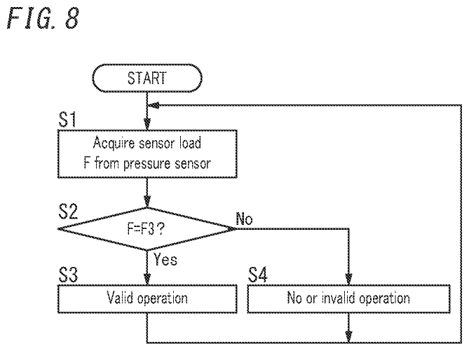

This detection method will be described in further detail with reference to FIG. 8.

The detection method is performed by the processing unit 11. Step S1 (acquisition step) includes acquiring a detection value (sensor load F) from the pressure sensor 6.

Thereafter, Step S2 (detection step) includes comparing the sensor load F with the reference value F3. If the sensor load F is equal to the reference value F3(if the answer is YES in Step S2), a decision is made that the moving member 2 have moved beyond a certain position corresponding to the reference value F3, i.e., a detection is made that a valid operation have been performed on the input device 10 (in Step S3). On the other hand, unless the sensor load F is equal to the reference value F3(if the answer is NO in Step S2), a decision is made that the moving member 2 have not moved beyond the certain position corresponding to the reference value F3. That is to say, a detection is made that either no operation or an invalid operation has been performed on the input device 10 (in Step S4).

The processing unit 11 performs this series of processing steps S1-S4 repeatedly at regular time intervals. Note that the flowchart shown in FIG. 8 shows just an exemplary detection method according to the present disclosure. Thus, the processing steps shown in FIG. 8 may be performed in a different order as appropriate, an additional processing step may be performed as needed, or at least one of the processing steps may be omitted as appropriate.

A program according to an aspect is designed to cause one or more processors to perform the detection method described above.

The input system 1 according to the present disclosure includes a computer system. The computer system includes, as principal hardware components thereof, a processor and a memory. At least some functions of the input system 1 according to the present disclosure may be performed by making the processor execute a program stored in the memory of the computer system. The program may be stored in advance in the memory of the computer system. Alternatively, the program may also be downloaded through a telecommunications line or be distributed after having been recorded in some non-transitory storage medium such as a memory card, an optical disc, or a hard disk drive, any of which is readable for the computer system. The processor of the computer system may be made up of a single or a plurality of electronic circuits including a semiconductor integrated circuit (IC) or a large-scale integrated circuit (LSI). As used herein, the “integrated circuit” such as an IC or an LSI is called by a different name depending on the degree of integration thereof. Examples of the integrated circuits include a system LSI, a very-large-scale integrated circuit (VLSI), and an ultra-large-scale integrated circuit (ULSI). Optionally, a field-programmable gate array (FPGA) to be programmed after an LSI has been fabricated or a reconfigurable logic device allowing the connections or circuit sections inside of an LSI to be reconfigured may also be adopted as the processor. Those electronic circuits may be either integrated together on a single chip or distributed on multiple chips, whichever is appropriate. Those multiple chips may be aggregated together in a single device or distributed in multiple devices without limitation. As used herein, the “computer system” includes a microcontroller including one or more processors and one or more memories. Thus, the microcontroller may also be implemented as a single or a plurality of electronic circuits including a semiconductor integrated circuit or a large-scale integrated circuit.

Also, in the embodiment described above, the plurality of functions of the input system 1 are aggregated together in a single device. However, this is not an essential configuration for the input system 1 and should not be construed as limiting. Alternatively, those constituent elements of the input system 1 may be distributed in multiple different devices. For example, the processing unit 11 may be provided separately from the input device 10. Still alternatively, at least some functions of the input system 1 (e.g., some functions of the processing unit 11) may be implemented as a cloud computing system as well.

Conversely, at least some functions, which are distributed in multiple devices according to the exemplary embodiment described above, of the input system 1, for example, may be aggregated together in a single device. For example, the functions distributed in the processing unit 11 and the control unit 101 may be aggregated together in a single device. The processor performing the functions of the processing unit 11 may also serve as a processor performing the functions of the control unit 101.

### Recapitulation

The embodiment and its variations described above may be specific implementations of the following aspects of the present disclosure.

An input device (10) according to a first aspect includes a moving member (2), a pressure sensor (6), and an inversion member (5). The moving member (2) moves downward. The pressure sensor (6) is pressed by downward movement of the moving member (2). The inversion member (5) is configured to, when a magnitude of the downward movement of the moving member (2) exceeds a predetermined threshold value (peak threshold value ST2), cause a load (F1) applied from the inversion member (5) to the pressure sensor (6) to stop increasing and start decreasing.

This configuration enables, by, for example, making a processing unit (11) provided outside of the input device (10) compare a detection value provided by the pressure sensor (6) with a reference value (F3), determining whether or not the moving member (2) has moved beyond a certain position (hereinafter referred to as an “operating point”) corresponding to the reference value (F3). In addition, this configuration also enables adjusting the operating point by setting the reference value (F3) at an appropriate value. That is to say, providing the input device (10) with the pressure sensor (6) makes the operating point adjustable.

An input device (10) according to a second aspect, which may be implemented in conjunction with the first aspect, further includes an elastic member (4). The elastic member (4) applies upward force to the moving member (2). The elastic member (4) is compressed by the downward movement of the moving member (2).

This configuration allows the moving member (2) that has moved downward to go back upward to its home position with the elastic force applied by the elastic member (4).

An input device (10) according to a third aspect, which may be implemented in conjunction with the first or second aspect, further includes a light source (81). The moving member (2) has a through hole (210), through which light emitted from the light source (81) passes.

This configuration may make the input device (10) impressive with the light emitted.

Note that the constituent elements according to the second and third aspects are not essential constituent elements for the input device (10) but may be omitted as appropriate.

An input system (1) according to a fourth aspect includes: the input device (10) according to any one of the first to third aspects; and a processing unit (11). The inversion member (5) transmits, to the pressure sensor (6), the load applied to the moving member (2). The pressure sensor (6) outputs a detection value representing the load applied by the downward movement of the moving member (2). The processing unit (11) detects, by comparing the detection value with a reference value (F3), that the moving member (2) has moved beyond a certain position corresponding to the reference value (F3).

This configuration enables adjusting the operating point by setting the reference value (F3) at an appropriate value.

An input system (1) according to a fifth aspect, which may be implemented in conjunction with the fourth aspect, further includes a preloading member (cover body 31). The preloading member maintains a preloading state. The preloading state is a state in which a load (F1) is applied from the moving member (2) to the pressure sensor (6) while the moving member (2) is not operated. The processing unit (11) uses, as the reference value (F3), a value corresponding to a load that is lighter than the load (F1) applied to the pressure sensor (6) in the preloading state.

This configuration may reduce the chances of the processing unit (11) erroneously detecting an operation on the moving member (2).

In an input system (1) according to a sixth aspect, which may be implemented in conjunction with the fifth aspect, while the load applied to the moving member (2) increases from the preloading state, the load transmitted from the inversion member (5) to the pressure sensor (6) reaches a minimum value (local minimum value F4) when the magnitude of movement is a predetermined bottom threshold value (ST4). The processing unit (11) uses, as the reference value (F3), a value equal to or greater than the minimum value (local minimum value F4).

This configuration may reduce the chances of the processing unit (11) erroneously detecting an operation on the moving member (2).

An input system (1) according to a seventh aspect, which may be implemented in conjunction with any one of the fourth to sixth aspects, further includes an input interface (103) that accepts an operation of setting the reference value (F3).

This configuration allows the user, for example, to set the reference value (F3).

Note that the constituent elements according to the fifth to seventh aspects are not essential constituent elements for the input system (1) but may be omitted as appropriate.

A detection method according to an eighth aspect is designed to use an input device (10) including a moving member (2), a pressure sensor (6), an elastic member (4), and an inversion member (5). The moving member (2) moves downward. The pressure sensor (6) outputs a detection value representing a load applied by the moving member (2) as the moving member (2) moves downward. The elastic member (4) applies upward force to the moving member (2). The inversion member (5) transmits, to the pressure sensor (6), the load applied to the moving member (2) by overcoming the upward force applied by the elastic member (4). The inversion member (5) is configured to, when a magnitude of the downward movement of the moving member (2) exceeds a predetermined threshold value (peak threshold value ST2), cause the load applied from the inversion member (5) to the pressure sensor (6) to stop increasing and start decreasing. The detection method includes an acquisition step and a detection step. The acquisition step includes acquiring the detection value from the pressure sensor (6). The detection step includes detecting, by comparing the detection value with a reference value (F3), that the moving member (2) has moved beyond a certain position corresponding to the reference value (F3).

This configuration enables adjusting the operating point by setting the reference value (F3) at an appropriate value.

Note that these are not the only aspects of the present disclosure but various configurations (including variations) of the input system (1) according to the exemplary embodiment described above may also be implemented as a detection method and a program.

### REFERENCE SIGNS LIST

1 Input System
2 Moving Member
4 Elastic Member
5 Inversion Member
6 Pressure Sensor
10 Input Device
11 Processing Unit
31 Cover Body (Preloading Member)
81 Light Source
103 Input Interface
210 Through Hole
F1 Load
F3 Reference Value
F4 Local Minimum Value (Minimum Value)
ST2 Peak Threshold Value (Predetermined Threshold Value)
ST4 Bottom Threshold Value

1. An input device comprising:
a moving member configured to move downward;
a pressure sensor configured to be pressed by downward movement of the moving member;
and an inversion member configured to, when a magnitude of the downward movement of the moving member exceeds a predetermined threshold value, cause a load applied from the inversion member to the pressure sensor to stop increasing and start decreasing.

2. The input device of claim 1, further comprising an elastic member configured to apply upward force to the moving member, wherein
the elastic member is configured to be compressed by the downward movement of the moving member.

3. The input device of claim 1, further comprising a light source, wherein
the moving member has a through hole, through which light emitted from the light source passes.

4. An input system comprising:
the input device of claim 1; and
a processing unit,
the inversion member being configured to transmit, to the pressure sensor, the load applied to the moving member,
the pressure sensor being configured to output a detection value representing the load applied by the downward movement of the moving member,
the processing unit being configured to detect, by comparing the detection value with a reference value, that the moving member has moved beyond a certain position corresponding to the reference value.

5. The input system of claim 4, further comprising a preloading member configured to maintain a preloading state in which a load is applied from the moving member to the pressure sensor while the moving member is not operated, wherein
the processing unit is configured to use, as the reference value, a value corresponding to a load that is lighter than the load applied to the pressure sensor in the preloading state.

6. The input system of claim 5, wherein
while the load applied to the moving member increases from the preloading state,
the load transmitted from the inversion member to the pressure sensor reaches a minimum value when the magnitude of movement is a predetermined bottom threshold value, and
the processing unit is configured to use, as the reference value, a value equal to or greater than the minimum value.

7. The input system of claim 4, further comprising an input interface configured to accept an operation of setting the reference value.

8. A detection method designed to use an input device, the input device including:
a moving member configured to move downward;
a pressure sensor configured to output a detection value representing a load applied by the moving member as the moving member moves downward;
an elastic member configured to apply upward force to the moving member; and
an inversion member configured to transmit, to the pressure sensor, the load applied to the moving member by overcoming the upward force applied by the elastic member, and also configured to, when a magnitude of the downward movement of the moving member exceeds a predetermined threshold value, cause the load applied from the inversion member to the pressure sensor to stop increasing and start decreasing,
the detection method comprising:
an acquisition step including acquiring the detection value from the pressure sensor; and
a detection step including detecting, by comparing the detection value with a reference value, that the moving member has moved beyond a certain position corresponding to the reference value.
